(19) United States
(12) Patent Application Publication
(10) Pub. No.: US 2024/0209507 A1
(43) Pub. Date: Jun. 27, 2024

(54) FILM FORMING APPARATUS

(71) Applicant: Tokyo Electron Limited, Tokyo (JP)

(72) Inventors: Manabu HONMA, Iwate (JP); Takuya OIKAWA, Iwate (JP); Noriaki FUKIAGE, Yamanashi (JP); Hiroyuki WADA, Yamanashi (JP)

(21) Appl. No.: 18/536,789

(22) Filed: Dec. 12, 2023

(30) Foreign Application Priority Data
Dec. 22, 2022 (JP) 2022-205689

(51) Int. Cl. C23C 16/458; C23C 16/46; H01J 37/32

(52) U.S. Cl. CPC C23C 16/4584; C23C 16/46; H01J 37/32724; H01J 2237/20214; H01J 2237/3321

(57) ABSTRACT

A film forming apparatus includes a processing chamber and a substrate support provided in the processing chamber. The substrate support includes a recess in which a substrate is placed. The recess includes a projection at a bottom surface thereof. The projection is provided along an outer periphery of the substrate placed in the recess.

### CROSS-REFERENCE TO RELATED APPLICATIONS

This application is based upon and claims priority to Japanese Patent Application No. 2022-205689, filed on Dec. 22, 2022, the entire contents of which are incorporated herein by reference.

### BACKGROUND

### 1. Field of the Invention

The present disclosure relates to film forming apparatuses.

### 2. Description of the Related Art

In, for example, Japanese Laid-Open Patent Publication Nos. 2010-056470 and 2013-222948, an apparatus configured to perform processing by supplying a processing gas to a circular substrate being placed and revolved on a rotation table in a processing chamber is known.

### SUMMARY

According to one aspect of the present disclosure, a film forming apparatus includes a processing chamber and a substrate support provided in the processing chamber. The substrate support includes a recess in which a substrate is placed. The recess includes a projection at a bottom surface thereof. The projection is provided along an outer periphery of the substrate placed in the recess.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a vertical cross-sectional view illustrating a film forming apparatus according to an embodiment;

FIG. 2 is a plan view illustrating an interior of the film forming apparatus according to the embodiment;

FIG. 3 is a plan view illustrating the interior of the film forming apparatus according to the embodiment;

FIG. 4 is a perspective view illustrating the interior of the film forming apparatus according to the embodiment;

FIG. 5 is a plan view illustrating a part of a rotation table according to a first example;

FIG. 6 is a cross-sectional view of FIG. 5, as taken along line A-A and as viewed in a direction indicated by arrows A;

FIG. 7 is a plan view illustrating a part of a rotation table according to a second example;

FIG. 8 is a cross-sectional view of FIG. 7, as taken along line B-B and as viewed in a direction indicated by arrows B;

FIG. 9 is a plan view illustrating a part of a rotation table according to a third example;

FIG. 10 is a cross-sectional view of FIG. 9, as taken along line C-C and as viewed in a direction indicated by arrows C;

FIG. 11 is a cross-sectional view of FIG. 9, as taken along line D-D and as viewed in a direction indicated by arrows D;

FIG. 12 is a plan view illustrating a part of a rotation table according to a fourth example;

FIG. 13 is a graph of a substrate sliding occurrence percentage; and

FIG. 14 is a graph of a particle occurrence percentage.

### DETAILED DESCRIPTION

The present disclosure provides a technique of being able to suppress sliding of a substrate over a substrate support.

Hereinafter, non-limiting embodiments of the present disclosure will be described with reference to the attached drawings. Throughout the attached drawings, the same or corresponding members or parts are designated by the same or corresponding reference symbols, and duplicate description thereof will be omitted.

### Film Forming Apparatus

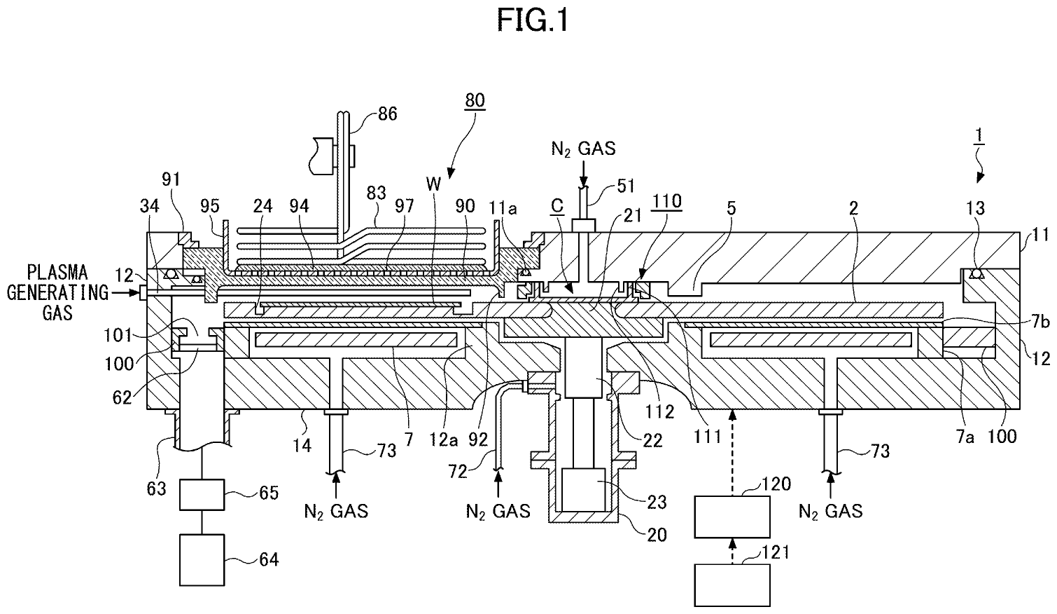

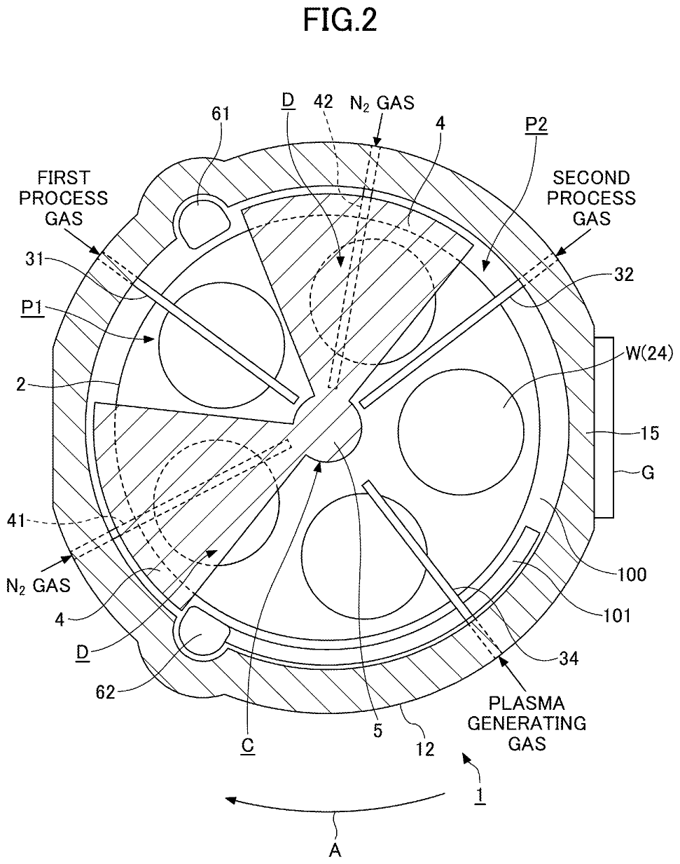

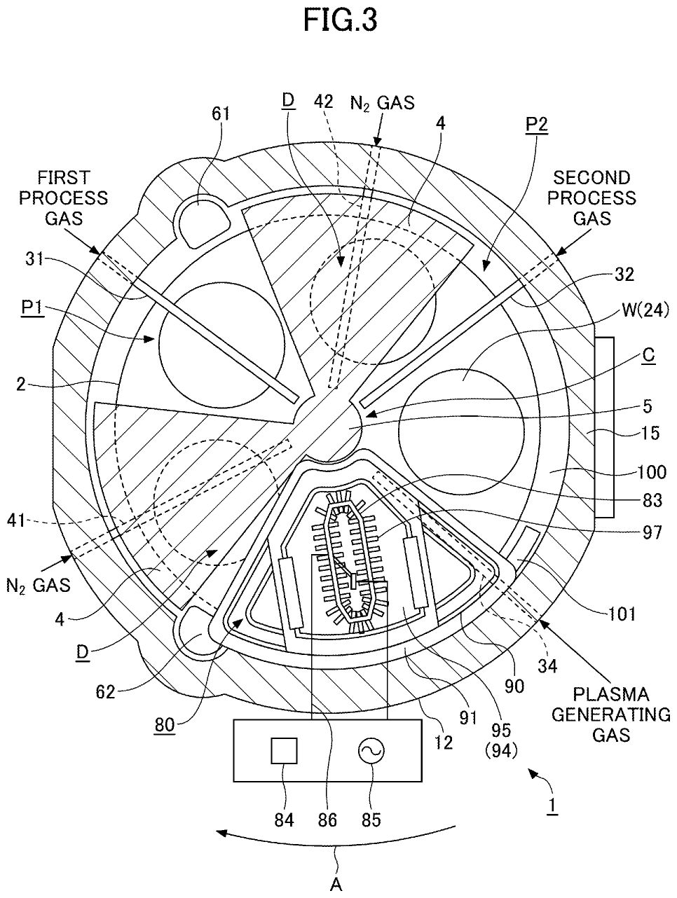

The film forming apparatus according to the embodiment will be described with reference to FIG. 1 to FIG. 4. FIG. 1 is a vertical cross-sectional view illustrating the film forming apparatus according to the embodiment. FIG. 2 is a plan view illustrating the interior of the film forming apparatus according to the embodiment. FIG. 3 is a plan view illustrating the interior of the film forming apparatus according to the embodiment. FIG. 4 is a perspective view illustrating the interior of the film forming apparatus according to the embodiment.

The film forming apparatus according to the embodiment includes a processing chamber 1 and a rotation table 2.

The processing chamber 1 has a circular shape in a plan view thereof. The processing chamber 1 includes a cover plate 11 and a chamber body 12. The cover plate 11 covers an opening in the upper surface of the chamber body 12. The cover plate 11 is provided detachably to the chamber body 12. A separating gas supply tube 51 is connected to the center of the cover plate 11. Through the separating gas supply tube 51, a separating gas is supplied to a center region C in the processing chamber 1. This suppresses mixing of different processing gases in the center region C in the processing chamber 1. The separating gas may be, for example, nitrogen (N₂) gas. A sealing member 13 is provided at the periphery of the upper surface of the chamber body 12. The sealing member 13 has a ring shape.

A heat generator 7, which is a heater, is provided above a bottom 14 of the processing chamber 1. The heat generator 7 is configured to heat a substrate W on the rotation table 2. The substrate W may be, for example, a semiconductor wafer. A cover member 7a is provided laterally of the heat generator 7. An overlaying member 7b is provided above the heat generator 7. The overlaying member 7b overlays the heat generator 7. A plurality of purge gas supply tubes 73 are provided in the bottom 14. The plurality of purge gas supply tubes 73 are provided along a circumferential direction of the processing chamber 1. Each of the purge gas supply tubes 73 is provided below the heat generator 7. Through each purge gas supply tube 73, a purge gas is supplied to a space in which the heat generator 7 is disposed. The purge gas may be, for example, N₂ gas.

The rotation table 2 is rotatably provided in the processing chamber 1. The rotation table 2 has a rotation center at the center of the processing chamber 1. The rotation table 2 is formed of, for example, quartz. The rotation table 2 is fixed to an approximately cylindrical core 21 at the center thereof. The rotation table 2 is configured to be rotatable (e.g., clockwise) about a vertical axis by a rotation shaft 22 that is connected to the lower surface of the core 21 and extends in a vertical direction. The lower end of the rotation shaft 22 is connected to a driver 23. The driver 23 rotates the rotation shaft 22 about the vertical axis. The rotation shaft 22 and the driver 23 are housed in a casing 20. The upper end of the casing 20 is airtightly attached to the lower surface of the bottom 14 of the processing chamber 1. The casing 20 is provided with a purge gas supply tube 72. Through the purge gas supply tube 72, the purge gas is supplied to a region below the rotation table 2. The purge gas may be, for example, N₂ gas. The outer periphery of the bottom 14 around the core 21 forms a projection 12a that is formed into a ring shape so as to become in proximity with the rotation table 2 from below.

A recess 24 is formed in the surface of the rotation table 2. The recess 24 has a circular shape in a plan view thereof. The substrate W is placed in the recess 24. A plurality of recesses 24 (e.g., five recesses 24) are provided along a rotation direction of the rotation table 2 (a direction indicated by arrow A in FIG. 2 and FIG. 3). Each of the recesses 24 has a size that is slightly larger than the substrate W. The recess 24 is provided with a plurality of through-holes 24a. Raising and lowering pins (not illustrated) are inserted into the plurality of through-holes 24a. The raising and lowering pins are for lifting the substrate W from below and for raising and lowering the substrate W. Details of the recess 24 will be described below.

Gas nozzles 31, 32, 34, 41, and 42 are provided at positions facing a passage region in the recesses 24.

The gas nozzles 31, 32, 34, 41, and 42 are radially disposed at intervals along the circumferential direction of the processing chamber 1. The gas nozzles 31, 32, 34, 41, and 42 are formed of, for example, quartz. The gas nozzles 31, 32, 34, 41, and 42 are attached toward the center region C from the lateral wall of the processing chamber 1. Also, the gas nozzles 31, 32, 34, 41, and 42 are attached so as to horizontally extend while facing the substrate W. For example, clockwise as viewed from the below-described transporting port 15 (in the rotation direction of the rotation table 2), the gas nozzle 34, the gas nozzle 41, the gas nozzle 31, the gas nozzle 42, and the gas nozzle 32 are arranged in this order.

The gas nozzle 31 is connected to a supply source of a first processing gas. The first processing gas may be, for example, a silicon-containing gas. The gas nozzle 32 is connected to a supply source of a second processing gas. The second processing gas may be gas that reacts with the first processing gas and yields a reaction product. The second processing gas may be, for example, a nitriding gas. The second processing gas may be an oxidizing gas. The gas nozzle 34 is connected to a supply source of a plasma generating gas. The plasma generating gas may be, for example, a gas mixture of argon (Ar) gas and oxygen (O₂) gas. The gas nozzles 41 and 42 are connected to supply sources of the separating gas. The separating gas may be, for example, N₂ gas. The lower surfaces of the gas nozzles 31, 32, 34, 41, and 42 are each provided with a plurality of gas-discharging holes along a radial direction of the rotation table 2.

A region below the gas nozzle 31 becomes a first processing region P1 in which the first processing gas is adsorbed to the substrate W. A region below the gas nozzle 32 is a second processing region P2 in which the first processing gas, adsorbed to the substrate W, and the second processing gas are reacted with each other. Regions below the gas nozzles 41 and 42 become separating regions D in which the first processing region P1 and the second processing region P2 are separated from each other.

As illustrated in FIG. 2 and FIG. 3, the cover plate 11 of the processing chamber 1 in the separating regions D is provided with approximately fan-shaped projections 4. The gas nozzles 41 and 42 are housed in the projections 4. At both sides of each of the gas nozzles 41 and 42 in the circumferential direction of the rotation table 2, first ceiling surfaces that are the lower surfaces of the projections 4 are disposed, in order to prevent mixing of the processing gases. At both sides of each of the first ceiling surfaces in the circumferential direction thereof, second ceiling surfaces higher than the first ceiling surfaces are disposed. In order to prevent mixing of the processing gases, the periphery of the projection 4 is folded in an L shape so as to face an outer end surface of the rotation table 2 and so as to be slightly apart from the chamber body 12.

Above the gas nozzle 34, a plasma generator 80 is provided. The plasma generator 80 is configured to generate a plasma from the plasma generating gas discharged from the gas nozzle 34. The plasma generator 80 is disposed from the center of the rotation table 2 to the outer periphery thereof so as to be across the passage region of the substrate W. The plasma generator 80 includes an antenna 83. The antenna 83 is formed of a metal wire that is wound into a coil. The antenna 83 is disposed so as to be airtightly compartmented from the inner region of the processing chamber 1. The antenna 83 is electrically connected to a high-frequency power source 85 via a matching device 84. The high-frequency power source 85 outputs, for example, a RF power of 13.56 megahertz (MHz).

The cover plate 11 above the gas nozzle 34 has an opening formed into an approximately fan shape in a plan view thereof. The opening is airtightly sealed with a housing 90. The housing 90 is formed of, for example, quartz. The housing 90 is formed so that the periphery thereof horizontally extends in the form of a flange in the circumferential direction and the center thereof is recessed toward the inner region of the processing chamber 1. The housing 90 houses the antenna 83 in an interior thereof. A sealing member 11a is provided between the housing 90 and the cover plate 11. A compressor 91 is provided at the periphery of the housing 90. The compressor 91 is configured to compress the periphery of the housing 90 downward. The plasma generator 80, the matching device 84, and the high-frequency power source 85 are electrically connected to each other via a connection electrode 86.

In order to inhibit entry of, for example, N₂ gas or ozone (O₃) gas into a region below the housing 90, as illustrated in FIG. 1, the periphery of the lower surface of the housing 90 vertically extends downward (the rotation table 2-side) entirely along the circumferential direction, thereby forming a projection 92 for restriction of gas. The gas nozzle 34 is housed in a region enclosed by the inner circumferential surface of the projection 92, the lower surface of the housing 90, and the upper surface of the rotation table 2.

As illustrated in FIG. 1 and FIG. 3, a Faraday shield 95 is provided between the housing 90 and the antenna 83. The Faraday shield 95 has an approximately box shape that is opened upward. The Faraday shield 95 is formed of a conductive plate. The Faraday shield 95 is grounded. Slits 97 are provided in the bottom surface of the Faraday shield 95. The slits 97 are provided below the antenna 83 entirely along the circumferential direction. The slits 97 are formed so as to extend in a direction that is orthogonal to a winding direction of the antenna 83. Of an electric field and a magnetic field generated in the antenna 83, the slits 97 inhibit the electric field from going toward the substrate W below the antenna 83, and enable the magnetic field to reach the substrate W. An insulating plate 94 is provided between the Faraday shield 95 and the antenna 83. The insulating plate 94 electrically insulates the Faraday shield 95 and the antenna 83 from each other. The insulating plate 94 is formed of, for example, quartz.

A side ring 100 having a ring shape is disposed outward of the rotation table 2 and slightly below the rotation table 2. The upper surface of the side ring 100 is provided with a first exhaust port 61 and a second exhaust port 62 that are apart from each other in the circumferential direction. The first exhaust port 61 is formed between the gas nozzle 31 and the separating region D that is downstream of the gas nozzle 31 in the rotation direction of the rotation table. The first exhaust port 61 is formed therebetween at a position closer to the separating region D. The second exhaust port 62 is formed between the gas nozzle 34 and the separating region D that is downstream of the gas nozzle 34 in the rotation direction of the rotation table. The second exhaust port 62 is formed therebetween at a position closer to the separating region D.

The first exhaust port 61 exhausts the first processing gas and the separating gas. The second exhaust port 62 exhausts the plasma generating gas in addition to the second processing gas and the separating gas. A gas-flow groove 101 is formed in the upper surface of the side ring 100 at the outer edge of the housing 90. The gas-flow groove 101 is for flowing gas into the second exhaust port 62 while avoiding the housing 90. As illustrated in FIG. 1, the first exhaust port 61 and the second exhaust port 62 are connected to a vacuum pump 64 through exhaust tubes 63 each including an intervening pressure adjuster 65 such as a butterfly valve or the like.

A projection 5 is provided at the center in the lower surface of the cover plate 11. As illustrated in FIG. 2, the projection 5 is formed into an approximately ring shape entirely extending along the circumferential direction so as to be continuous with a portion of the projection 4 closer to the center region C. The lower surface of the projection 5 may be, for example, the same height as the height of the lower surface of the projection 4. A labyrinth structure 110 is formed above the core 21 closer to the rotation center of the rotation table 2 than the projection 5. The labyrinth structure 110 suppresses mixing of the first processing gas and the second processing gas in the center region C. The labyrinth structure 110 includes a first wall 111 and a second wall 112. The first wall 111 vertically extends from the rotation table 2 toward the cover plate 11 and is formed entirely along the circumferential direction. The second wall 112 vertically extends from the cover plate 11 toward the rotation table 2 and is formed entirely along the circumferential direction. The first wall 111 and the second wall 112 are alternatingly arranged in the radial direction of the rotation table 2.

The transporting port 15 is provided in the lateral wall of the processing chamber 1. As illustrated in FIG. 2 and FIG. 3, the transporting port 15 is a port through which delivery of the substrate W is performed between an external transporting arm (not illustrated) and the rotation table 2. The transporting port 15 is airtightly opened and closed by a gate valve G. Below a position of the rotation table 2 that is at the same angle position as the transporting port 15, the raising and lowering pins (not illustrated) for lifting the substrate W via the through-holes 24a of the rotation table 2 are provided.

The film forming apparatus includes a controller 120. The controller 120 may be, for example, a computer. The controller 120 is configured to control movements of the whole apparatus. A memory of the controller 120 stores programs for performing various processes. The programs include a group of steps constructed so as to perform the movements of the film forming apparatus. The programs are installed in the controller 120 from a storage 121, which is a storage medium, such as a hard disk, a compact disk, a magneto-optical disk, a memory card, a flexible disk, or the like.

### Rotation Table

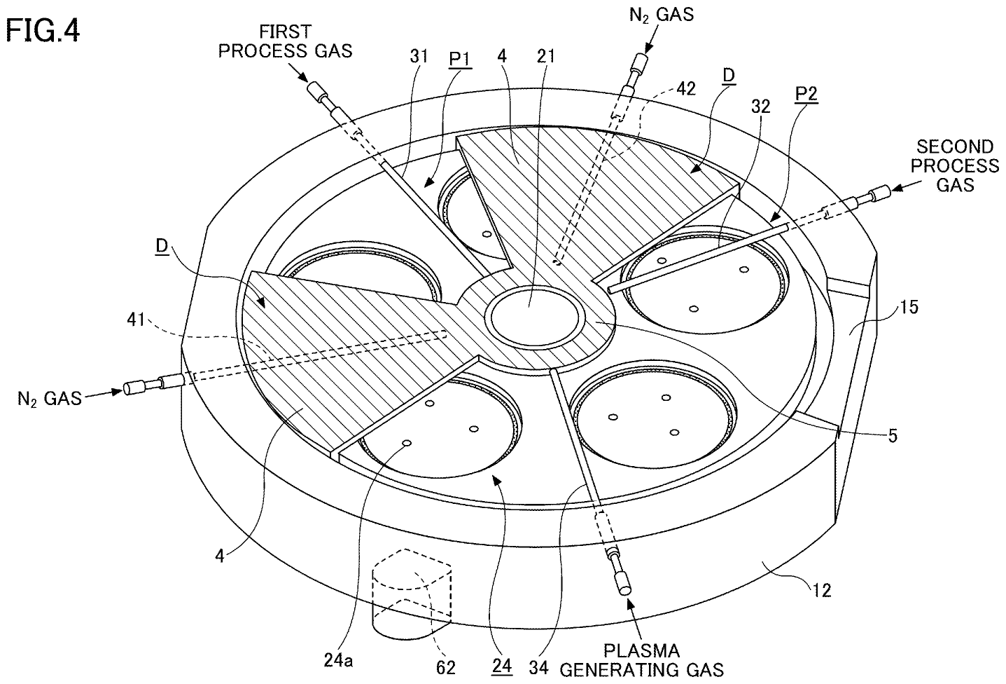

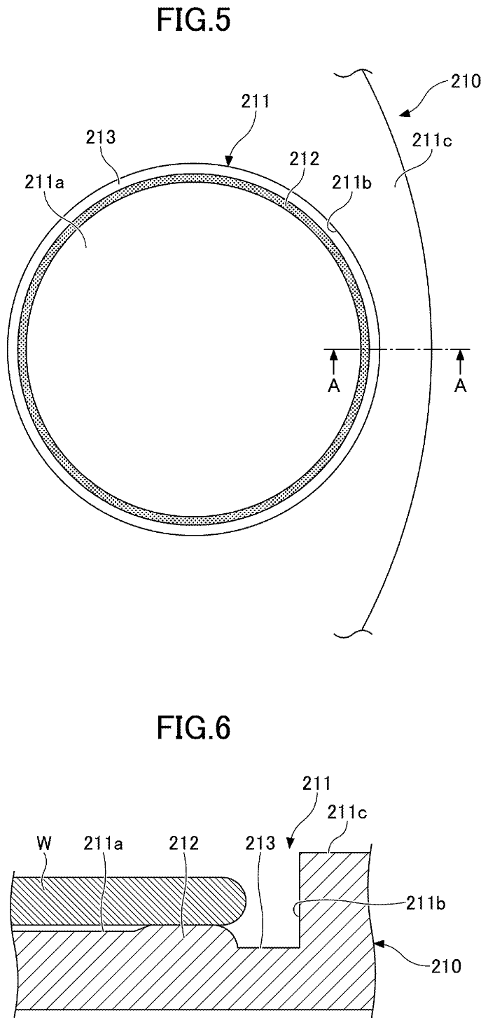

A rotation table 210 according to the first example, which is applicable as the rotation table 2, will be described with reference to FIG. 5 and FIG. 6. FIG. 5 is a plan view illustrating a part of the rotation table 210 according to the first example. FIG. 6 is a cross-sectional view of FIG. 5, as taken along line A-A and as viewed in a direction indicated by arrows A. FIG. 5 omits illustration of the substrate W.

The rotation table 210 includes a plurality of recesses 211 that are provided along the rotation direction. The substrate W is placed in the recess 211. The inner diameter of the recess 211 is larger than the outer diameter of the substrate W placed in the recess 211. In one example, the outer diameter of the substrate W is 300 millimeters (mm), and the inner dimeter of the recess 211 is 302 mm. The recess 211 includes a bottom surface 211a, a lateral surface 211b, and an upper surface 211c.

The bottom surface 211a is provided with a projection 212. The projection 212 is provided along the outer periphery of the substrate W placed in the recess 211. In this case, the outer periphery of the substrate W is supported by the projection 212, and a film having a high coefficient of friction is formed on the surface of the projection 212 from gas that entered near the projection 212 from the gap between the outer periphery of the substrate W and the lateral surface 211b of the recess 211. Therefore, it is possible to suppress sliding of the substrate W in the recess 211. The projection 212 has a ring shape extending along the outer periphery of the substrate W in a plan view thereof. The height of the projection 212 may be lower than the height of the upper surface 211c of the recess 211. The height of the projection 212 may be, for example, 5 micrometers (μm) or more and 50 μm or less. The height of the projection 212 is preferably 10 μm or more and 20 μm or less. In this case, the outer periphery of the substrate W is readily supported by the projection 212. The width of the projection 212 may be, for example, 5 mm or less. For example, the projection 212 is formed integrally with the rotation table 210. The projection 212 may be formed separately from the rotation table 210.

A groove 213 is provided in the bottom surface 211a. The groove 213 is provided outward of the projection 212. The groove 213 has a ring shape in a plan view thereof. The boundary between the projection 212 and the groove 213 is positioned, for example, inward of the outer end of the substrate W. The boundary between the projection 212 and the groove 213 may be at the same position as the outer end of the substrate W, or may be positioned outward of the outer end of the substrate W. The groove 213 may be absent. In the absence of the groove 213, a path through which gas enters near the projection 212 becomes shorter.

The rotation table 210 as described above includes a plurality of recesses 211 provided along the rotation direction, and the recesses 211 each include the projection 212 provided along the outer periphery of the substrate W placed in the recess 211. In this case, the outer periphery of the substrate W is supported by the projection 212, and a film having a high coefficient of friction is formed on the surface of the projection 212 from gas that entered near the projection 212 from the gap between the outer periphery of the substrate W and the lateral surface 211b of the recess 211. Therefore, it is possible to suppress sliding of the substrate W in the recess 211. As a result, the sliding of the substrate W in contact with the lateral surface 211b is suppressed, and thus it is possible to suppress occurrence of particles due to the sliding between the substrate W and the lateral surface 211b.

Meanwhile, in the absence of the projection 212 in the recess 211, when a difference in pressure between above the substrate W and below the substrate W occurs due to, for example, change in pressure in the processing chamber 1, a frictional force between the bottom surface 211a and the lower surface of the substrate W becomes smaller. When this frictional force is small, the substrate W slides over the bottom surface 211a due to a centrifugal force occurring through rotation of the rotation table 210, and contacts the lateral surface 211b. In this state, when the substrate W is thermally expanded or when lift pins raise or lower the substrate W, the substrate W and the lateral surface 211b slide over each other, and particles occur.

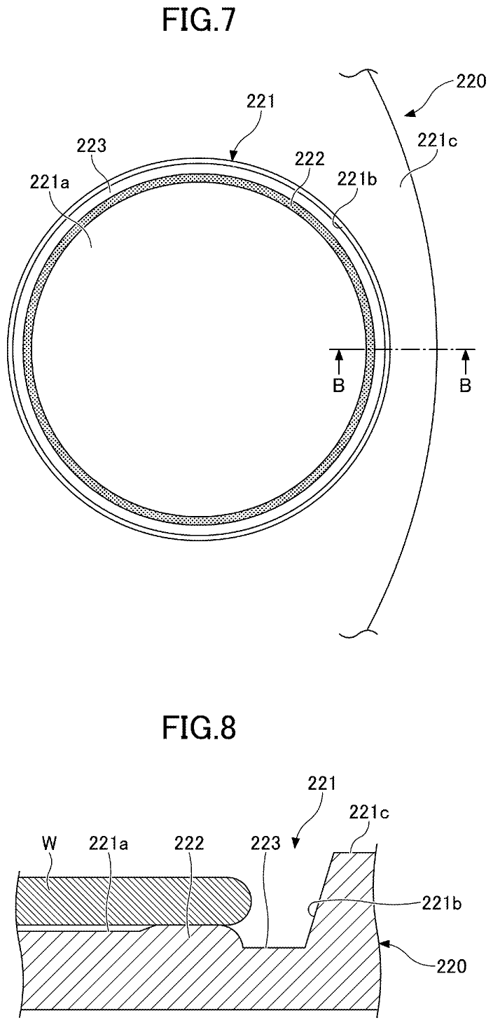

A rotation table 220 according to the second example, which is applicable as the rotation table 2, will be described with reference to FIG. 7 and FIG. 8. FIG. 7 is a plan view illustrating a part of the rotation table 220 according to the second example. FIG. 8 is a cross-sectional view of FIG. 7, as taken along line B-B and as viewed in a direction indicated by arrows B. FIG. 7 omits illustration of the substrate W.

The rotation table 220 is different from the rotation table 210 in that the rotation table 220 includes a tilted surface 221b instead of the lateral surface 211b. The other configurations of the rotation table 220 may be the same as in the rotation table 210. In the following, the difference from the rotation table 210 will be mainly described.

The rotation table 220 includes a plurality of recesses 221 that are provided along the rotation direction. The recess 221 includes a bottom surface 221a, a tilted surface 221b, and an upper surface 221c.

The bottom surface 221a is provided with a projection 222 and a groove 223. The projection 222 and the groove 223 may be the same as the projection 212 and the groove 213, respectively.

The tilted surface 221b is tilted so as to extend outward from the bottom surface 221a toward the upper surface 221c. In this case, the fluid conductance in the gap between the outer periphery of the substrate W and the tilted surface 221b becomes higher, and gas readily enters toward the projection 222 from the gap. Therefore, a film having a high coefficient of friction is formed on the surface of the projection 222 at an early stage.

The above-described rotation table 220 also produces similar effects to the effects of the rotation table 210.

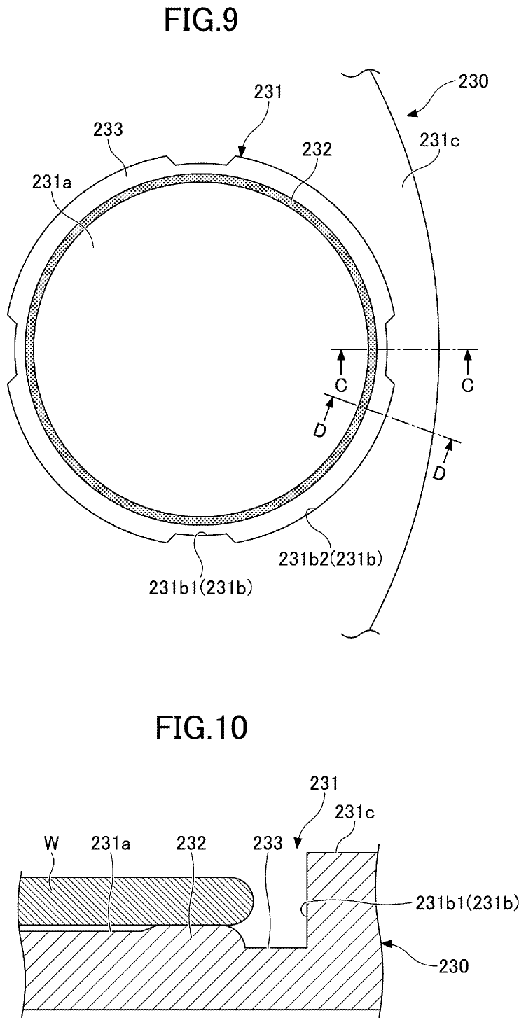

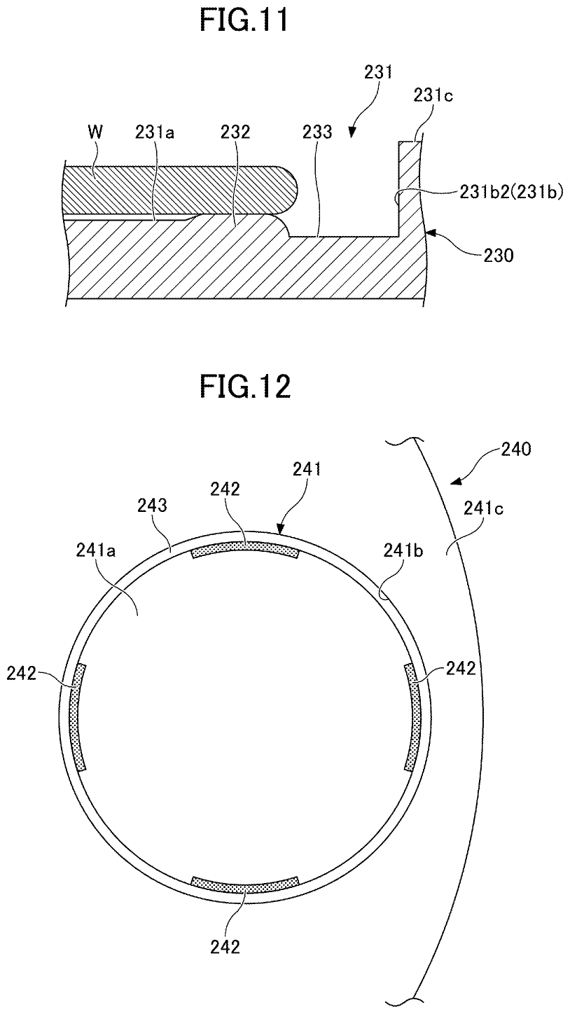

A rotation table 230 according to the third example, which is applicable as the rotation table 2, will be described with reference to FIG. 9 to FIG. 11. FIG. 9 is a plan view illustrating a part of the rotation table 230 according to the third example. FIG. 10 is a cross-sectional view of FIG. 9, as taken along line C-C and as viewed in a direction indicated by arrows C. FIG. 11 is a cross-sectional view of FIG. 9, as taken along line D-D and as viewed in a direction indicated by arrows D. FIG. 9 omits illustration of the substrate W.

The rotation table 230 is different from the rotation table 210 in that the rotation table 230 includes, instead of the lateral surface 211b, a lateral surface 231b increased in diameter at parts thereof in the circumferential direction. The other configurations of the rotation table 230 may be the same as in the rotation table 210. In the following, the difference from the rotation table 210 will be mainly described.

The rotation table 230 includes a plurality of recesses 231 that are provided along the rotation direction. The recess 231 includes a bottom surface 231a, a lateral surface 231b, and an upper surface 231c.

The bottom surface 231a is provided with a projection 232 and a groove 233. The projection 232 and the groove 233 may be the same as the projection 212 and the groove 213, respectively.

The inner diameter of the lateral surface 231b is increased in at least a part of the circumferential direction. The inner diameter of the recess 231 at a part where the inner diameter of the lateral surface 231b is increased may be, for example, 304 mm. The lateral surface 231b may include first lateral surfaces 231b1 that are not increased in diameter, and second lateral surfaces 231b2 that are increased in diameter, with the first lateral surfaces 231b1 and the second lateral surfaces 231b2 being alternatingly provided along the circumferential direction of the recess 231. In one example, four first lateral surfaces 231b1 and four second lateral surfaces 231b2 are alternatingly provided.

In the circumferential direction of the recess 231, the gap between the outer end of the substrate W and the second lateral surface 231b2 is larger than the gap between the outer end of the substrate W and the first lateral surface 231b1. In this case, the fluid conductance in the gap between the outer periphery of the substrate W and the lateral surface 231b becomes higher, and gas readily enters toward the projection 232 from the gap. Therefore, a film having a high coefficient of friction is formed on the surface of the projection 232 at an early stage. Also, the first lateral surfaces 231b1, which are not increased in diameter, are provided at parts of the recess 231 in the circumferential direction, and thus when the substrate W is horizontally moved, the movement of the substrate W is restricted by the first lateral surfaces 231b1.

The length of the first lateral surface 231b1 in the circumferential direction may be, for example, shorter than the length of the second lateral surface 231b2 in the circumferential direction. In this case, gas readily enters toward the projection 232 from the gap between the outer periphery of the substrate W and the lateral surface 231b. The length of each of the four first lateral surfaces 231b1 in the circumferential direction may be, for example, 6 mm.

The above-described rotation table 230 also produces similar effects to the effects of the rotation table 210.

A rotation table 240 according to the fourth example, which is applicable as the rotation table 2, will be described with reference to FIG. 12. FIG. 12 is a plan view illustrating a part of the rotation table 240 according to the fourth example. FIG. 12 omits illustration of the substrate W.

Therotation table 240 is different from the rotation table 210 in that the rotation table 240 includes, instead of the projection 212 having the ring shape in the plan view thereof, a plurality of projections 242 each having an arc shape in a plan view thereof. In the following, the difference from the rotation table 210 will be mainly described.

The rotation table 240 includes a plurality of recesses 241 that are provided along the rotation direction. The recess 241 includes a bottom surface 241a, a lateral surface 241b, and an upper surface 241c.

The bottom surface 241a is provided with a projection 242 and a groove 243. The groove 243 may be the same as the groove 213.

A plurality of projections 242 are provided along the outer periphery of the substrate W. The plurality of projections 242 are provided at intervals along the circumferential direction of the recess 241. The projection 242 has, for example, an arc shape in a plan view thereof. No particular limitation is imposed on the shape of the projection 242. The projection 242 may have a circular shape in a plan view thereof. The projection 242 may have a rectangular shape in a plan view thereof. In this way, the projections 242 may be provided at parts of the recess 241 in the circumferential direction.

The above-described rotation table 240 also produces similar effects to the effects of the rotation table 210.

### EXAMPLES

In Example 1, a film forming apparatus including the recess 231 as illustrated in FIG. 9 to FIG. 11 was used to repeatedly perform a film-forming process of forming a silicon nitride film on a substrate. Also, every time the cumulative film thickness of the silicon nitride film reached a predetermined thickness, the number of substrates that were in contact with the lateral surface 231b of the recess 231 and the number of substrates that were not in contact with the lateral surface 231b of the recess 231 were confirmed, thereby calculating a percentage of the substrates that were in contact with the lateral surface 231b of the recess 231 (hereinafter this percentage is referred to as a “substrate sliding occurrence percentage”). Moreover, when the cumulative film thickness of the silicon nitride film was 2 μm or larger, the number of particles adhered to a predetermined in-plane region of the substrate was confirmed, thereby calculating a percentage of the substrates in which the number of the particles adhered was equal to or more than a predetermined number (hereinafter this percentage is referred to as a “particle occurrence percentage”).

In Example 2, a film forming apparatus including the recess 211 as illustrated in FIG. 5 and FIG. 6 was used, and the substrate sliding occurrence percentage and the particle occurrence percentage were calculated in the same procedure as in Example 1.

In Comparative Example 1, a film forming apparatus including the recess 211 identical to the recess 211 as illustrated in FIG. 5 and FIG. 6 except for the absence of the projection 212 was used, and the substrate sliding occurrence percentage and the particle occurrence percentage were calculated in the same procedure as in Example 1.

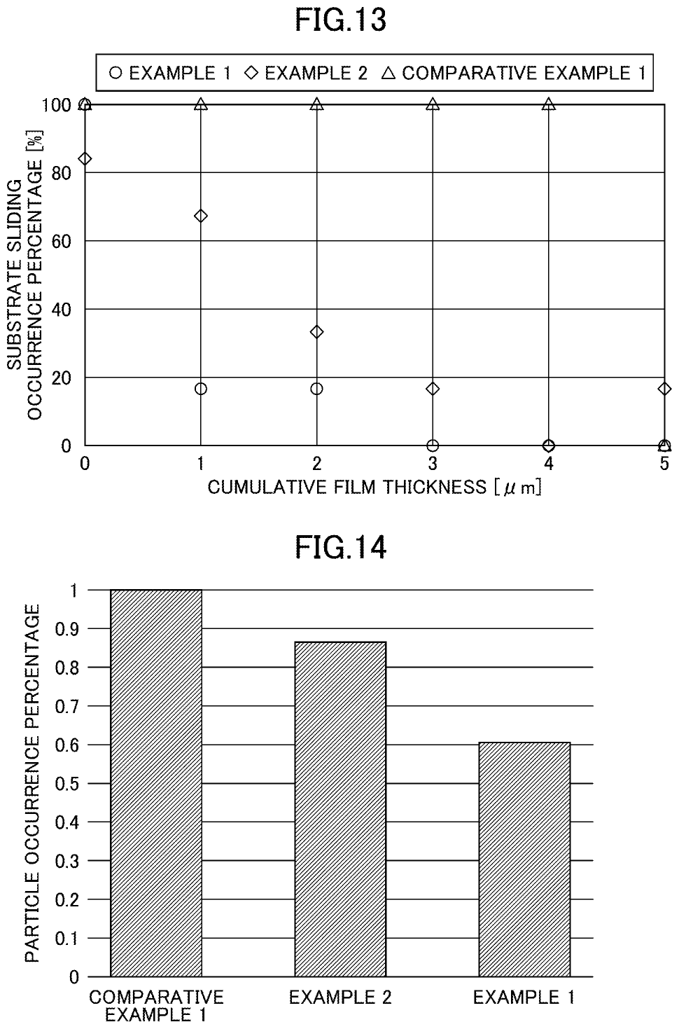

FIG. 13 is a graph of the substrate sliding occurrence percentage. In FIG. 13, the horizontal axis indicates the cumulative film thickness [μm] and the vertical axis indicates the substrate sliding occurrence percentage [%]. In FIG. 13, circular marks indicate the results of Example 1, rhombic marks indicate the results of Example 2, and triangular marks indicate the results of Comparative Example 1.

As indicated in FIG. 13, in Example 1, when the cumulative film thickness was 1 μm or larger, the substrate sliding occurrence percentage was lower than 20%, and when the cumulative film thickness was 3 μm or larger, the substrate sliding occurrence percentage was 0%. In Example 2, when the cumulative film thickness was 3 μm or smaller, the substrate sliding occurrence percentage was lower as the cumulative film thickness increased, and when the cumulative film thickness was 3 μm or larger, the substrate sliding occurrence percentage was stable in the range of from 0% to 20%. In Comparative Example 1, when the cumulative film thickness was 4 μm or lower, the substrate sliding occurrence percentage was 100%, and when the cumulative film thickness was 5 μm, the substrate sliding occurrence percentage was 0%.

The above results indicate that when the cumulative film thickness is 4 μm or smaller, the effect of suppressing the sliding of the substrate in the recess is higher in Examples 1 and 2 than in Comparative Example 1. That is, it is indicated that by providing the projection along the outer periphery of the substrate placed in the recess, it is possible to suppress the sliding of the substrate in the recess when the cumulative film thickness is smaller.

The above results indicate that when the cumulative film thickness is 3 μm or smaller, the effect of suppressing the sliding of the substrate in the recess is much higher in Example 1 than in Example 2. That is, it is indicated that by providing the projection along the outer periphery of the substrate placed in the recess and increasing the inner diameter of the recess in at least a part of the circumferential direction, it is possible to suppress the sliding of the substrate in the recess when the cumulative film thickness is smaller. This is likely because when the inner diameter of the recess is increased in at least a part of the circumferential direction, a silicon nitride film becomes readily formed on the surface of the projection, the silicon nitride film having a higher coefficient of friction relative to the substrate than a material forming the projection.

FIG. 14 is a graph of the particle occurrence percentage. FIG. 14 indicates the results of Comparative Example 1, Example 2, and Example 1 in order from the left. In FIG. 14, the particle occurrence percentages in Example 1, Example 2, and Comparative Example 1 are expressed as a relative value with the particle occurrence percentage in Comparative Example 1 being 1.

As illustrated in FIG. 14, the particle occurrence percentage decreases by about 14% in Example 2 compared to Comparative Example 1. This result indicates that by providing the projection along the outer periphery of the substrate placed in the recess, it is possible to suppress adhering of particles to a predetermined in-plane region of the substrate.

As illustrated in FIG. 14, the particle occurrence percentage decreases by about 40% in Example 1 compared to Comparative Example 1. This result indicates that by providing the projection along the outer periphery of the substrate placed in the recess and increasing the inner diameter of the recess in at least a part of the circumferential direction, it is possible to especially suppress adhering of particles to a predetermined in-plane region of the substrate.

According to the present disclosure, it is possible to suppress sliding of the substrate over the substrate support.

It should be understood that the embodiments disclosed herein are illustrative and not restrictive in all respects. Various omissions, substitutions, and changes may be made to the above-described embodiments without departing from the scope of claims recited and the spirit of the present disclosure.

The above-described embodiments are related to embodiments in which the film forming apparatus is configured to revolve a plurality of substrates W by the rotation table 2, which are placed on the rotation table 2 in the processing chamber 1, so that the substrates W sequentially pass through a plurality of regions, thereby performing a process to the substrates W; however, the present disclosure is not limited to this. For example, the film forming apparatus may be a single wafer processing apparatus including a substrate support provided, in a surface thereof, with a single recess in which the substrate W is placed, and being configured to process a single substrate placed on the substrate support.

What is claimed is:

1. A film forming apparatus, comprising:
a processing chamber; and
a substrate support provided in the processing chamber, the substrate support including a recess in which a substrate is placed, wherein
the recess includes a projection at a bottom surface thereof, and
the projection is provided along an outer periphery of the substrate placed in the recess.

2. The film forming apparatus according to claim 1, wherein
the recess includes a groove in the bottom surface thereof, and
the groove is provided outward of the projection.

3. The film forming apparatus according to claim 1, wherein
a height of the projection is lower than an upper surface of the recess.

4. The film forming apparatus according to claim 1, wherein
the projection has a ring shape extending along the outer periphery of the substrate.

5. The film forming apparatus according to claim 1, wherein
the projection is a plurality of projections that are provided along the outer periphery of the substrate.

6. The film forming apparatus according to claim 1, wherein
an inner diameter of the recess is larger than an outer diameter of the substrate.

7. The film forming apparatus according to claim 1, wherein
an inner diameter of the recess is increased in at least a part of a circumferential direction of the recess.

8. The film forming apparatus according to claim 1, wherein
the recess is tilted so as to extend from the bottom surface toward an upper surface of the recess in at least a part of a circumferential direction of the recess.

9. The film forming apparatus according to claim 1, further comprising:
a heater configured to heat the substrate placed in the recess.

10. The film forming apparatus according to claim 1, wherein
the substrate support is rotatable, and
the recess is a plurality of recesses that are provided along a rotation direction of the substrate support.

11. The film forming apparatus according to claim 2, wherein
the substrate support is rotatable, and
the recess is a plurality of recesses that are provided along a rotation direction of the substrate support.

12. The film forming apparatus according to claim 3, wherein
the substrate support is rotatable, and
the recess is a plurality of recesses that are provided along a rotation direction of the substrate support.

13. The film forming apparatus according to claim 4, wherein
the substrate support is rotatable, and
the recess is a plurality of recesses that are provided along a rotation direction of the substrate support.

14. The film forming apparatus according to claim 5, wherein
the substrate support is rotatable, and
the recess is a plurality of recesses that are provided along a rotation direction of the substrate support.

15. The film forming apparatus according to claim 6, wherein
the substrate support is rotatable, and
the recess is a plurality of recesses that are provided along a rotation direction of the substrate support.

16. The film forming apparatus according to claim 7, wherein
the substrate support is rotatable, and
the recess is a plurality of recesses that are provided along a rotation direction of the substrate support.

17. The film forming apparatus according to claim 8, wherein
the substrate support is rotatable, and
the recess is a plurality of recesses that are provided along a rotation direction of the substrate support.

18. The film forming apparatus according to claim 9, wherein
the substrate support is rotatable, and
the recess is a plurality of recesses that are provided along a rotation direction of the substrate support.
